(19) United States
(12) Patent Application Publication
(10) Pub. No.: US 2005/0263774 A1
(43) Pub. Date: Dec. 1, 2005

(54) Polycrystalline Si thin film structure and fabrication method thereof and method of fabricating TFT using the same

(75) Inventors: Do-young Kim, Gyeonggi-do (KR); Takashi Noguchi, Gyeonggi-do (KR); Hans S. Cho, Seoul (KR); Jang-yeon Kwon, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd, Gyeonggi-do (KR)

(21) Appl. No.: 11/136,536

(22) Filed: May 25, 2005

(30) Foreign Application Priority Data
May 25, 2004 (KR) 10-2004-0037322

(51) Int. Cl. H01L 29/04; H01L 21/84

(52) U.S. Cl. 257/75; 438/486; 438/487; 438/166

(57) ABSTRACT

Provided are a high quality poly-Si structure and a method of fabricating the same. The poly-Si structure includes a substrate, a polycrystallized silicon thin film, and an adhesive layer disposed between them. In the method of fabricating the poly-Si structure, an adhesive layer is first formed on a substrate, a-Si is deposited at a low temperature, and a polycrystallization process of silicon is, then performed by high density energy. Polycrystallization by high energy is possible, and therefore, high quality poly-Si can be achieved. The method can be employed in a low-temperature process, and a heat-sensitive material such as plastic or the like can be used as a substrate.

### CROSS-REFERENCE TO RELATED PATENT APPLICATION

This application claims the priority of Korean Patent Application No. 10-2004-0037322, filed on May 25, 2004, in the Korean Intellectual Property Office, the disclosure of which is incorporated herein in its entirety by reference.

### BACKGROUND OF THE INVENTION

1. Field of the Invention

The present invention relates to a polycrystalline silicon thin film structure and a fabrication method thereof, and more particularly, to a method of fabricating high quality polycrystalline silicon by suppressing the separation of silicon during a polycrystallization process by high density energy.

2. Description of the Related Art

Polycrystalline silicon (poly-Si) is applied in various electronic products such as solar battery, or the like as well as flat panel displays, since it has a higher mobility than that of amorphous silicon (a-Si). Generally, a poly-Si electronic device is formed on a substrate, which is composed of a material, such as a highly heat resistant glass, or the like. However, recently, studies are actively processed on a method of forming a poly-Si electronic device on a plastic substrate. In order to prevent the thermal deformation of plastic, it is inevitably employed a method of forming a poly-Si electronic device at a low temperature, so-called, low-temperature film formation process. The low-temperature film formation process is necessary to prevent thermal stress against a substrate, but it is also necessary to suppress process defects caused by a high-temperature process during the fabrication of a device. Since the plastic substrate is light-weighted, flexible, and durable, it is studied as the substrate of flat panel displays recently.

However, the plastic has a defect of being heat-sensitive, and therefore, a low-temperature process is required in the use of the plastic for an LCD. Carey, et al. proposed a method of preventing a damage of plastic in the process of forming a silicon channel on a plastic substrate (U.S. Pat. No. 5,817,550).

A material deposition method requiring a process temperature of 400° C. cannot be applied to a plastic substrate, which is thermally deformed at a temperature of, for example, 200° C. Further, it is difficult to achieve a poly-Si thin film having a large diameter at a process temperature below 200° C., and silicon dioxide having a flat-band voltage near 0 V by the method proposed by Y.-J Tung, et al. and S. D. Theiss, et al. (see Y.-J Tung, X. Meng. T.-J. King. P. G. Carey, P. M. Smith, S. D. Theiss, R. Weiss, G. A. Davis V. Aebi, Tech, Digest of SID98, pp. 887˜890; D. D. Theiss, P. G. Carey, P. M. Smith, P. Wickboldt, T. W. Sigmon, Y. J. Tung, T.-J King, IEDM 98, pp. 257˜260)

A conventional method of fabricating poly-Si uses a CVD or a PECVD technique. By the deposition method, a-Si is achieved, and through the annealing of this, poly-Si is achieved. That is, the conventional method essentially includes an annealing process in order to achieve poly-Si. However, the PECVD technique generates a large number of defects in a silicon film in the polycrystallization process by annealing due to the existence of a large amount of residual hydrogen.

A generally-employed deposition method of an a-Si thin film is a CVD or a PECVD technique, but the sputtering technique using a noble gas, for example, Ar gas is preferred in order to achieve high quality poly-Si since 10˜20% of hydrogen exists inside crystal. The sputtering technique using Ar gas provides a capture rate as low as 1˜3%. The quality of poly-Si is further improved with a lowered hydrogen capture rate, and for the reason, it is required to develop a method of reducing a capture rate of the gas used in the formation of Si.

Since the sputtering technique used to deposit an a-Si thin film uses a noble gas, residual hydrogen does not exist in the silicon, but the sputtering technique has a limit in high density energy of annealing treatment for high quality poly-Si because the silicon film may be separated from the substrate with the energy above a predetermined level during the annealing treatment process.

### SUMMARY OF THE INVENTION

The present invention provides a poly-Si structure and a method of fabricating the same, which can be realized by a low-temperature deposition, and allows an annealing treatment with high density energy.

According to an aspect of the present invention, there is provided a poly-Si thin film structure, which includes a substrate, an adhesive layer formed on the substrate, and a poly-Si thin film formed on the adhesive layer.

According to another aspect of the present invention, there is provided a method of fabricating a poly-Si thin film, which includes forming an adhesive layer, which will be well adhered with a-Si, on the surface of a substrate such as plastic or glass, depositing a-Si on the adhesive layer, and annealing the a-Si with high energy.

According to a further aspect of the present invention, there is provided a method of fabricating a TFT, which includes a substrate, a poly-Si active layer formed on the substrate, a gate insulating layer formed on the active layer, and a gate formed on the gate insulating layer. The formation of the active layer includes forming an adhesive layer on the substrate, forming an a-Si thin film on the adhesive layer, and annealing the a-Si.

Further, the adhesive layer may be composed of SiNₓ. In the deposition of the a-Si, a low-temperature deposition such as a sputtering technique may be used, and an eximer laser, or the like may be used in the annealing treatment.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic sectional view of a poly-Si thin film structure according to the present invention;

FIGS. 2A through 2C are sectional views illustrating the processing sequences of a method of fabricating a poly-Si thin film structure according to the present invention;

FIG. 3 is an SEM image of the poly-Si fabricated according to the present invention;

FIG. 4 is an SEM image of the poly-Si fabricated by a conventional method;

FIG. 5 is schematic flow chart of a method of fabricating a TFT according to the present invention; and

FIG. 6 is a schematic sectional view of the TFT fabricated according to the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

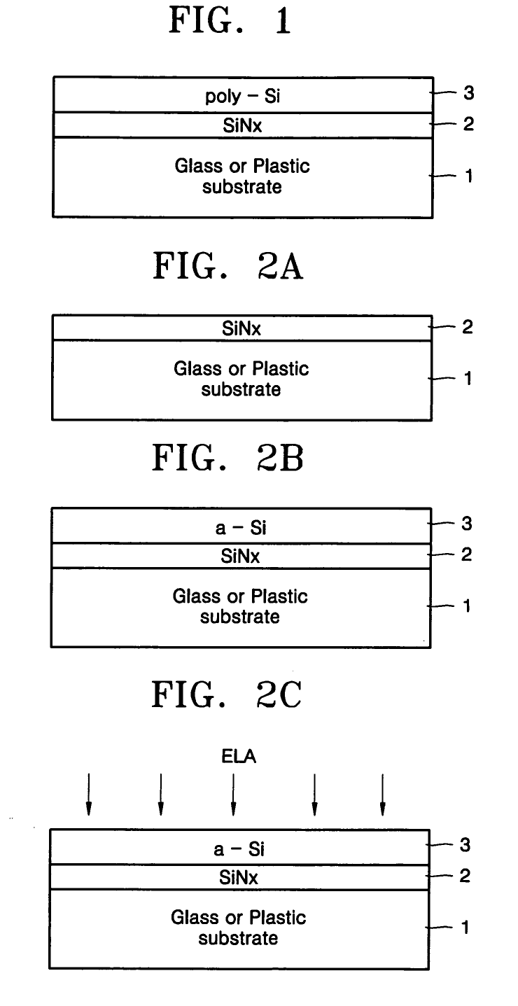

FIG. 1 is a schematic sectional view of a poly-Si thin film structure according to the present invention.

A substrate 1 is glass or plastic. An SiO₂ thin film, which is formed of a naturally or artificially electric insulating layer, may be formed on the surface of the glass or the plastic. It is omitted in the drawing for convenience. An adhesive layer 2 is formed on the substrate 1. The material of the adhesive layer 2 may utilize any material having a good adhesiveness with the a-Si, which will be formed on the adhesive layer 2, and changed to a polycrystalline phase, and preferably, is composed of silicon nitride (SiNₓ) with a thickness of about 20 nm.

A poly-Si thin film 3 is formed on the adhesive layer 2. The poly-Si thin film 3 is grown with a thickness as much as desired, and it has a thickness of, for example, about 50 nm.

The poly-Si thin film structure fabricated according to the present invention as shown in FIG. 1 is one complete unit, but may be a semi-manufactured goods to be employed as a component element of one electronic product. The poly-Si thin film structure according to the present invention can be applied in a thin film transistor, a solar battery, or any application products requiring a poly-Si thin film, and such a application product is apparently within a range of the present invention as long as it has the structure as above.

Hereinafter, a description will be made on a method of fabricating a poly-Si thin film according to the present invention.

As shown in FIG. 2A, an adhesive layer 2 is deposited on a substrate 1 by a CVD technique, and the like. The adhesive layer 2 is composed of, for example, SiNₓ, and has a thickness of about 20 nm.

As shown in FIG. 2B, an a-Si thin film 3 is formed on the adhesive layer 2 with a predetermined thickness. A sputtering gas used in the sputtering technique allowing a low-temperature deposition utilizes noble gas, for example, Ar gas. The a-Si is controlled to have 50 nm in thickness. A sputtering power is 200 W and a gas pressure is 5 mTorr.

As shown in FIG. 2C, the a-Si thin film 3 is annealed by ELA (eximer laser annealing). The ELA is performed several times gradually increasing the energy for a predetermined time. In the present invention, a furnace or an eximer laser can be employed for the annealing of the a-Si thin film, and preferably, an eximer laser is used.

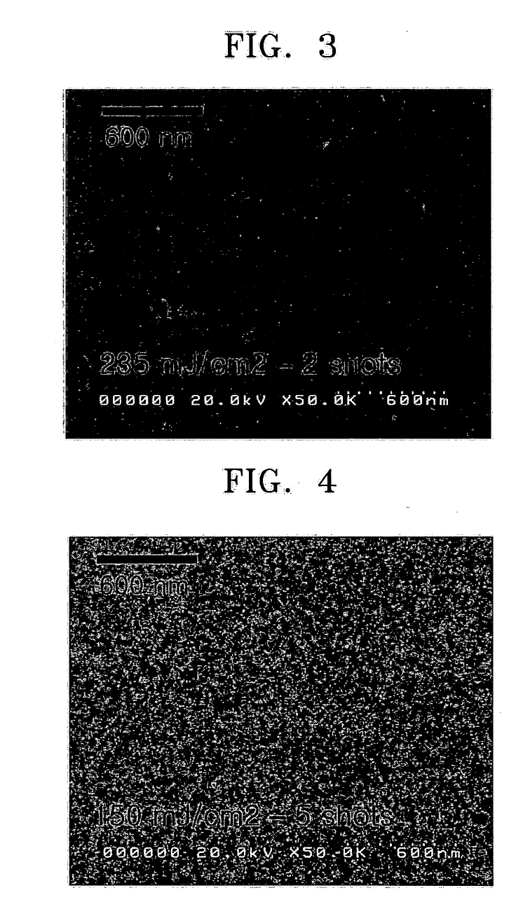

FIG. 3 is an SEM image of the poly-Si fabricated according to the present invention, and FIG. 4 is an SEM image of the poly-Si fabricated by a conventional method to compare the poly-Si fabricated according to the present invention.

The poly-Si fabricated according to the present invention as shown in FIG. 3 is achieved by irradiating 235 mJ/cm² of energy two times, whereas FIG. 4 shows a polycrystallized resultant structure of the silicon, which is directly formed on a substrate without an adhesive layer between them, and formed by irradiating 150 mJ/cm² of energy five times. According to the present invention, since a-Si is formed by a sputtering, the a-Si thin film does not include hydrogen, and therefore, a dehydrogenation process is necessary. Therefore, energy is irradiated with a desired high level at one time, unlike the conventional method of gradually increasing energy as the conventional ELA.

As shown in FIG. 3, the poly-Si according to the present invention is annealed with a very high density of energy, but the poly-Si is not separated from the substrate, and has a very large diameter even though it was annealed by such high density energy.

However, the resultant structure of FIG. 4, which is fabricated by annealing with energy as low as 150 mJ/cm², is separated from the substrate, and has a smaller diameter than that of the poly-Si of the present invention as well.

As known by, a maximum level of energy to provide high quality poly-Si is about 250 mJ/cm². In consideration of this, the silicon can be annealed with energy near the maximum level of energy according to the present invention, and the high quality poly-Si can be achieved.

Test results of the annealing of poly-Si according to the present invention and by a conventional method are shown in following Tables.

Table 1 represents a result by a conventional method of fabricating poly-Si without an adhesive layer, and Table 2 represents a result of the method according to the present invention utilizing an adhesive layer.

TABLE 1
Without SiNx layer

| | | | Energy density(mJ/cm2) | | | | | | |
|---|---|---|---|---|---|---|---|---|---|
| | | | 100 | 150 | 170 | 200 | 235 | 250 | 275 |
| Ar | The number | 1 | ◯ | ◯ | | X | | | |
| | of shots | 2 | ◯ | ◯ | | | | | |
| | (shots) | 5 | ◯ | ◯ | | | | | |
| | | 10 | ◯ | ◯ | | | | | |
| | | 20 | ◯ | X | | | | | |
| | | 30 | ◯ | X | | | | | |
| Xe | The number | 1 | ◯ | ◯ | | X | | | |
| | of shots | 2 | ◯ | ◯ | | | | | |
| | (shots) | 5 | ◯ | ◯ | | | | | |
| | | 10 | ◯ | X | | | | | |
| | | 20 | | | | | | | |
| | | 30 | | | | | | | |

TABLE 2
With SiNx layer

| | | | Energy density (mJ/cm2) | | | | | | |
|---|---|---|---|---|---|---|---|---|---|
| | | | 100 | 150 | 170 | 200 | 235 | 250 | 275 |
| Ar | The number | 1 | | | ◯ | ◯ | ◯ | X | |
| | of shots | 2 | | | | | ◯ | X | |
| | (shots) | 5 | | | | ◯ | X | | |
| | | 10 | | | | | | | |
| | | 20 | | | | | | | |
| | | 30 | | | | | | | |
| Xe | The number | 1 | | | ◯ | ◯ | ◯ | ◯ | X |
| | of shots | 2 | | | | | ◯ | ◯ | |
| | (shots) | 5 | | | | ◯ | ◯ | | |
| | | 10 | | | | ◯ | | | |
| | | 20 | | | | | | | |
| | | 30 | | | | | | | |

In comparison with Table 1 and Table 2, it can be seen that high quality poly-Si can be fabricated by the method according to the present invention. In Tables, marks, “O” and “X” represent samples in experiment, and O means that poly-Si is remained by the annealing under the corresponding conditions, and X means that poly-Si is separated, or damaged by the annealing. As shown in Table 1, the poly-Si fabricated without an adhesive layer was separated or damaged with the energy of 200 mJ/cm². However, according to the present invention, the poly-Si was all successfully fabricated by the annealing with the energy of 200 mJ/cm², but it was partially damaged or separated with the energy above 200 mJ/cm². Further, it shows that poly-Si was fabricated by an Xe sputtering method more stably than an Ar sputtering method.

The method of fabricating the poly-Si described as above is the most important process in the fabrication of a TFT, and other processes employ generally-known processes, which will be schematically explained in the following.

The characteristics of the method of fabricating a TFT according to the present invention is to realize a high-quality TFT on a heat-sensitive substrate such as plastic by fabricating poly-Si through a room-temperature process. That is, plastic can be utilized as the substrate of a TFT according to the present invention.

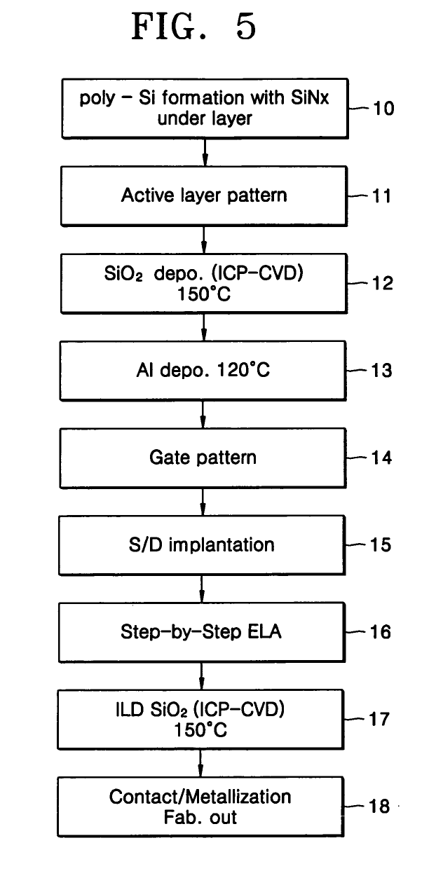

Referring to the process sequences shown in FIG. 5, a poly-Si thin film is formed on a substrate in accordance with the method of the present invention described as above. Here, an Xe sputtering method is preferably used in the deposition of a-Si (10).

After the a-Si is deposited, it is annealed by ELA, thereby forming a poly-Si thin film. The poly-Si thin film formed as above is patterned in the form of an active layer (11). The patterning uses a dry etch method such as RIE or the like, which is generally known.

After the active layer is formed, an SiO₂ thin film to be used as a gate insulating layer is formed (12).

After the SiO₂ gate insulating layer is formed, a metal layer such as Al, or the like is deposited at a temperature of 120° C. (13), and it is patterned, thereby forming a gate (electrode) (14).

In order to form source and drain regions after the gate is formed, an impurity implantation (S/D implantation) is performed, and an annealing by ELA is performed by a normal method (16).

After the source and drain regions are formed, for example, an SiO₂ is formed as an ILD (intermetal dielectric) by ICP-CVD at a temperature of 150° C. (17), and a formation of contact holes and a metallization are, then performed (18), thereby forming a poly-Si TFT.

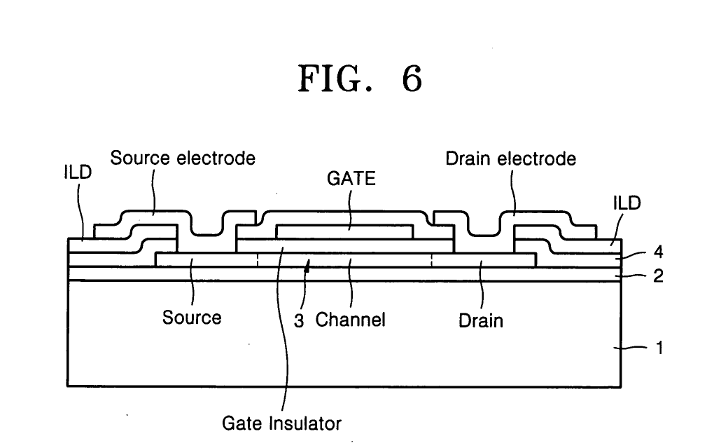

FIG. 6 is a schematic sectional view of the TFT fabricated according to the present invention.

As shown in FIG. 6, an SiNₓ layer is formed as an adhesive layer 2 on a substrate 1. A poly-Si film 3 is formed on the adhesive layer 2, and it is divided into a doped source, a drain, and a channel between them. A gate insulating layer 4 is formed on the poly-Si film 3, and through holes are formed at the positions corresponding to the source and the drain respectively, in order to provide contacts with a source electrode and a drain electrode, which are disposed on the source and the drain.

A gate (or gate electrode) GATE is formed above the channel and between the source electrode and the drain electrode, and an ILD (interlayer dielectric) is formed thereon. The ILD also has through holes at the positions corresponding to the source electrode and the drain electrode respectively. The source electrode is connected to the source of the poly-Si, and the drain electrode is connected to the drain of the poly-Si.

As described above, according to the present invention, a-Si can be formed at a room temperature, and it can be polycrystalized by very high density energy. The present invention provides advantages in that the silicon formed on a plastic is annealed with high density energy without a use of very expensive equipment such as the equipment for a CVD process, and an allowable energy range is very wide.

The method of fabricating a poly-Si thin film according to the present invention is suitable to employed in the fabrication of flat panel displays, particularly, an AMLCD, an AMOLED, a solar battery, a semiconductor memory device, or the like, which use plastic as a substrate. Also, the poly-Si thin film is very suitable to being used in a TFT, which requires a high mobility and a high-speed response capability, and uses plastic as a substrate. Further, the TFT can be employed to any electronic products as well as the AMLCD, and the AMOLED, as long as the electronics use the TFT as a switching device or an amplifying device.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A poly-Si thin film structure comprising:
a substrate;
an adhesive layer formed on the substrate; and
a poly-Si thin film formed on the adhesive layer.

2. The poly-Si thin film structure of claim 1, wherein the adhesive layer is an SiNₓ layer.

3. A method of fabricating a poly-Si thin film comprising:
forming an adhesive layer on a surface of a substrate;
forming an a-Si thin film on the adhesive layer; and
annealing the a-Si, thereby polycrystalizing the a-Si.

4. The method of claim 3, wherein the adhesive layer is a silicon nitride layer.

5. The method of claim 3, wherein the a-Si thin film is formed by a room-temperature sputtering technique.

6. The method of claim 4, wherein the a-Si thin film is formed by a room-temperature sputtering technique.

7. The method of claim 4, wherein the annealing is performed by excimer laser annealing (ELA).

8. The method of claim 5, wherein the annealing is performed by excimer laser annealing (ELA).

9. The method of claim 6, wherein the annealing is performed by excimer laser annealing (ELA).

10. A method of fabricating a TFT including a substrate, a poly-Si active layer formed on the substrate, a gate insulating layer formed on the active layer, and a gate formed on the gate insulating layer, in which the formation of the active layer comprises:
forming an adhesive layer on the substrate;
forming an a-Si thin film on the adhesive layer; and
annealing the a-Si.

11. The method of claim 10, wherein the adhesive layer is a silicon nitride layer.

12. The method of claim 10, wherein the a-Si thin film is formed by a room-temperature sputtering technique.

13. The method of claim 11, wherein the a-Si thin film is formed by a room-temperature sputtering technique.

14. The method of claim 10, wherein the annealing is performed by excimer laser annealing (ELA).

15. The method of claim 11, wherein the annealing is performed by excimer laser annealing (ELA).
